(19) United States
(12) Patent Application Publication
(10) Pub. No.: US 2003/0027427 A1
(43) Pub. Date: Feb. 6, 2003

(54) Integrated system for oxide etching and metal liner deposition

(75) Inventors: Diana Xiaobing Ma, Saratoga, CA (US); Sy Yuan Shieh, Palo Alto, CA (US); Yan Ye, Saratoga, CA (US); Tetsuya Ishikawa, Saratoga, CA (US); Gary C. Hsueh, Cupertino, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/922,980

(22) Filed: Aug. 6, 2001

(51) Int. Cl. H01L 21/311; C23C 16/00

(52) U.S. Cl. 438/700; 118/719

(57) ABSTRACT

An integrated process and system for etching a hole in an oxide layer and conformally coating a liner for metal filling. The wafer with a patterned photoresist mask is loaded into a first transfer chamber held at a vacuum of less than 1 Torr. An oxide etch reactor etches the oxide down to a nitride etch stop and barrier layer to form a hole through the oxide. Thereafter, the photoresist is ashed, and the barrier layer is removed. The wafer is transferred through a gated vacuum passageway to a second transfer chamber held at a vacuum no more than 10⁻⁶ Torr. In at least two PVD or CVD deposition chambers connected to the second transfer chamber, a barrier layer of Ta/TaN is coated onto sides of the hole and a copper seed layer is deposited over the barrier layer. The invention may be limited to the operations subsequent to ashing.

### BACKGROUND OF THE INVENTION

1. Field of the Invention

The invention relates generally to forming a via in an integrated circuit. In particular, the invention relates to an integrated system and process for plasma etching of oxide to form a via hole and then filling metallization into the hole without exposing the wafer to the atmosphere.

2. Background Art

The increased number of devices in advanced semiconductor integrated circuits, particularly for the more randomly arranged logic circuits such as microprocessors, has required increased number of wiring or metallization levels to provide for the complex electrical connections between the devices. Five and more metallization levels are becoming common. Each level includes a dielectric layer, for example, an oxide layer of silicon dioxide with a thickness of between about 0.7 and 1.3 μm. Via holes are etched through the dielectric layer to reach a conductive feature in the underlying structure, and the via hole is then filled with the metallization to provide a vertical interconnect to the underlying feature. A metallization is also defined on the top surface of the dielectric layer to provide a horizontal interconnect between different portions of the integrated circuit.

Properly, vias refer to vertical connections between multiple wiring levels while contacts refer to vertical connections from the silicon device to the first wiring level. Contacts require more demanding processing than vias because of the need to protect the semiconducting silicon and to make an ohmic contact between the silicon and the metallization. However, for purposes of the invention, contacts do not present fundamental differences over vias, and, unless stated otherwise, a via will be understood to include a contact.

Some of the more advanced integrated circuits use copper as the metallization in a dual-damascene structure. This structure allows a single metallization step to form both the vertically extending vias and the horizontally extending interconnects without the need to etch copper, a difficult technology. Copper is preferred over aluminum because of its lower resistivity and reduced susceptibility to electromigration.

Conventionally, the inter-level dielectric layers have been oxide layers formed of silica of the approximate composition SiO₂ or related silicate glasses such as borophosphosilicate glass (BPSG). However, these materials have a relatively high dielectric constant k of about 3.9 but even with process variations the value is limited to k>4.0. In view of the increased operating frequencies of advanced integrated circuits and the reduced spacing between conductive features, such as buses, there has been much recent development in low-k inter-level dielectric materials having reduced dielectric constants of less than 3.9. Doped silica such as fluorosilicate glass (FSG) has a dielectric constant of somewhat over 3. Other low-k dielectrics are being developed based either on silicon or carbon, but almost all of which can be characterized as oxides. Many of these low-k dielectric materials, particularly those having ultra low dielectric constants of k<2.2, have a stability problem relative to silica in that upon being exposed to air, they absorb or react with water vapor, with a resultant increase in the dielectric constant. The problem is particularly acute when a partially fabricated wafer having an exposed low-k dielectric layer is moved from one processing platform to another. Not only in most production line is the dielectric material exposed to air as a wafer bearing cassette is manually moved between platforms, but the duration of the exposure can both be long and be of varying lengths because of variable processing queues and other fabricational uncertainties such as work shift changes and equipment maintenance and breakdown and repair.

One conventional fabrication method of a dual-damascene inter-level dielectric structure and its metallization will be described with reference to several cross-sectional views of the developing structure. This particular exemplary method is generally referred to as “via first” dual damascene. As illustrated in FIG. 1, a lower-level dielectric layer 10, possibly of a low-k dielectric material includes a copper feature 12 recessed in its surface. A thin barrier layer 14, also acting as an etch stop layer, and an upper level dielectric layer 16 are deposited over the lower-level dielectric layer 10 and its copper feature 12. The barrier layer may be formed of, for example, silicon nitride (SiNₓ, where x may range between 1 and 1.5), BLOk™ (available from Applied Materials of Santa Clara), carbon rich nitride, silicon caribide or a spin-on dielectric. Exemplary nitride thicknesses are 20 to 100 nm. This layer is generally referred to as stop layer 1. Optionally, a second stop layer 19 is provided to deliniate the bottom of the trench.

An extended via hole 18 is etched through the upper-level dielectric layer 16, through the optional stop layer 19, and over the copper feature 12 in a process that etches oxide selectively to nitride so that the hole 18 stops on the stop/barrier layer 14. A plasma etching process, using, for example, a fluorocarbon and argon with the possible addition of a polymerizing gas and with substantial wafer biasing, is capable of etching a vertical hole of high aspect ratio in oxide with high selectivity to nitride.

An etching mask is then formed by depositing a photoresist layer 20 and photographically patterning it with a trench mask aperture. A multi-step process is used to form the trench and final via. A trench oxide etch step etches, as illustrated in the cross-sectional view of FIG. 2, only part way through the upper dielectric layer 16 to form a trench 26 and via hole 28. The depth of the trench can be determined either by using a stop layer 19, by using in-situ metrology to determine the etch depth, or by timed etch. The trench 26 is intended to provide a horizontally extending interconnect between multiple vias to the underlying metallization or to a via to a yet further overlying metallization. The underlying copper feature 12 may be formed in the trench of the underlying metallization level.

The oxide etching chemistry is typically similar to that used in etching the extended via hole 18. Because the stop layer 14 at the bottom of the extended via hole 18 is exposed to the trench etch plasma during the entire trench etching process, the oxide etch must be highly selective to barrier layer. This may be accomplished with a heavily polymerizing chemistry which forms a protective carbonaceous polymeric layer 30 on non-oxide surfaces, such as the stop layer 14, as well as on oxide sidewalls.

After the trench oxide etch, an ashing step removes the photoresist 20 and the polymer layer 30 to produce the structure of FIG. 3. Both the photoresist 20 and the polymer layer 30 are composed of carbonaceous polymer so both are usually etched by the same chemistry. Then, as illustrated in FIG. 4, a stripping step removes the portion of the stop layer 14 at the bottom of the via hole 28.

Thereafter, as illustrated in FIG. 5, a liner/barrier layer 32 is coated approximately conformally into the via hole 28 and the trench 26 and over the field area 34 on top of the dielectric layer 16. The barrier layer 32 is intended to prevent the diffusion between copper and the oxygen-containing dielectric. It may also serve as a glue layer over the oxide dielectric and as a nucleation layer for copper deposition. The barrier layer 32 for copper metallization is typically composed of tantalum-based materials, TaN or Ta/TaN, but tungsten and TiN are sometimes included. Multi-layer barriers are often used. The barrier deposition is typically at least partially performed by sputtering, and the barrier sputtering step is usually preceded by a plasma preclean step to remove any oxide or other residue that may have accumulated while the wafer was being transferred into the sputtering chamber. A Ta/TaN bilayer can be sputter deposited in a single sputter reactor with a tantalum target in a two-step process in which nitrogen is admitted to the chamber in the second step.

A thin copper seed layer 36 is typically sputter deposited over the barrier layer 32 in a nearly conformal process. The barrier layer 32 and the copper seed layer 36 are together referred to as the metal liner since they line the sides of the dual-damascene hole prior to the principal copper deposition. The copper seed deposition is preferably done using an enhanced self-ionized plasma (SIP⁺) sputter reactor having a target with an annularly shaped vault in its surface and a magnetron creating a localized high density plasma at low chamber pressure. Gopalraja et al. describe this reactor in U.S. patent application, Ser. No. 09/703,601, filed Nov. 1, 2000.

Thereafter, in steps not directly relevant to the invention, copper is filled into the hole, preferably by electrochemical plating (ECP). The copper seed layer 34 acts as both to nucleate the copper deposition and as an electrode for ECP. The ECP copper deposition is deposited to not only fill the etched hole but also to extend over the field area 34 at the top of the upper dielectric layer 16. Chemical mechanical polishing (CMP) removes the copper outside the etched hole but stops on the harder oxide on the field area 34 outside of the trench 26.

Conventionally, the oxide etch step is performed in a single-wafer plasma etch reactor, which may be a capacitively coupled diode reactor, a magnetically enhanced reactive ion etcher, or a inductively coupled high density plasma reactor specifically designed for the rich chemistries involving polymerization. On the other hand, the ashing step in an oxide etch process conventionally uses an oxygen plasma and is conventionally performed in a multi-wafer plasma reactor, such as a hexode reactor or a barrel reactor, or in a single wafer chamber such as the ASP available from Applied Materials. The stripping step involves a fluorocarbon etch similar to oxide etching but with leaner and cleaner chemistry so that selectivity to nitride is reduced. The lean chemistry may be accomplished with the addition of oxygen, the elimination of a polymerizing gas, or using a fluorocarbon with a higher fluorine fraction. The stop layer stripping step is typically performed in a single-wafer etch reactor similar to that for the oxide etch but preferably optimized for the lean stripping chemistry.

Conventionally also, the sputter deposition is performed in a separate processing platform which may include multiple sputter reactors for the different compositions being sputtered. Because the underlying copper feature is exposed to air after the barrier removal and hence is likely to oxidize, the sputtering usually is immediately preceded by precleaning the copper contact in a plasma preclean chamber located on the sputtering platform.

The above described process presents additional problems when used with a low-k inter-level dielectric. As the partially processed wafers are being transferred in cassettes between the different processing platforms, they are exposed to water-containing air, thus subjecting them not only to oxidation but probably more importantly to the uptake of water, which tends to increase the dielectric constant. The problem is exacerbated by the queuing problem inherent in a multi-platform system subject to different scheduling on the different platforms. The queuing time between process steps performed on different platforms is characterized by variability determined by work in progress (WIP). The queuing time may vary from minutes to days. Although the effect of atmospheric exposure may be overcome by a post-exposure anneal in order to recover the k value, a variable exposure may necessitate the complication of a variable time or temperature for the anneal.

### SUMMARY OF THE INVENTION

The present invention provides for various methods and systems for producing the dual damascene structure without exposing the wafer to the atmosphere. Additionally, according to the embodiments of the present invention all the processes are done on a single mainframe, thereby preventing the need to move the wafers in cassettes between mainframes.

According to one embodiment, an integrated process includes etching an oxide layer or a barrier and sputtering or CVD depositing metal and metal barrier layers one a single mainframe. Separate plasma processing chambers are connected to the mainframe through respective slit valves allowing the vacuum levels in the stages to be maintained independently of the processing pressures. Substrates are passed between the stages through gated passages allowing different vacuum levels to be maintained throughout processing of many substrates.

According to a second embodiment, the mainframe is divided into two separate vacuum sections which can maintain independent vacuum levels therein. According to yet a third embodiment, the first section of the mainframe is a first stage which is maintained at a pressure of no more than 1 Torr, preferably no more than 150 milliTorr. The section is a second stage which is maintained at a pressure of no more than 10⁻⁶ Torr, preferably no more than 10⁻⁸ Torr. The first stage is used for the various etching/ashing processes, while the second stage is used for the various sputtering processes.

According to an exemplary embodiment of the inventive integrated processing system, the reactors required of the process are provided on a single mainframe having a vacuum loading mechanism. In one particular embodiment the mainframe includes two isolatable vacuum stages.

### BRIEF DESCRIPTION OF THE DRAWINGS

FIGS. 1 through 5 are cross-sectional views of the conventional developing dual-damascene structure during trench oxide etch and metal lining.

FIG. 6 is a flow diagram of an integrated process for oxide etch and metal lining according to one embodiment of the invention.

FIG. 7 is a schematic plan view of an embodiment of the inventive integrated process tool on which the integrated process of FIG. 6 may be performed.

FIG. 8 is a diagram of an exemplary structure for a trench first dual damascene process.

FIG. 9 is a flow diagram of an integrated process for oxide etch and metal lining according to another embodiment of the invention.

FIG. 10 is a schematic plan view of another embodiment of the inventive integrated process tool on which the integrated process of FIGS. 6 or 9 may be performed.

FIG. 11 is a flow diagram of an integrated process for barrier removal and metal lining according to a second embodiment of the invention.

### DETAILED DESCRIPTION OF EXEMPLARY EMBODIMENTS

The invention includes several related aspects. One aspect involves an integrated process in which the barrier removal at the bottom of an etched via is performed on the same processing platform as the subsequent sputter deposition of the barrier lining the via hole, thereby allowing the oxide layer, particularly a moisture-sensitive low-k dielectric layer, to not be exposed to air. Another aspect involves a staged-vacuum platform in which etching and stripping steps are performed in plasma processing chambers connected to the higher-pressure stage, though the higher pressure is much less than atmospheric pressure, and the sputtering is performed in plasma sputter reactors connected to the lower-pressure stage. Yet another aspect of the invention involves integrating the oxide etching and metal lining in the same platform and using a process integration which prevents exposing the wafer to the atmosphere. Other aspect can be appreciated from the following description of exemplary embodiments of the invention.

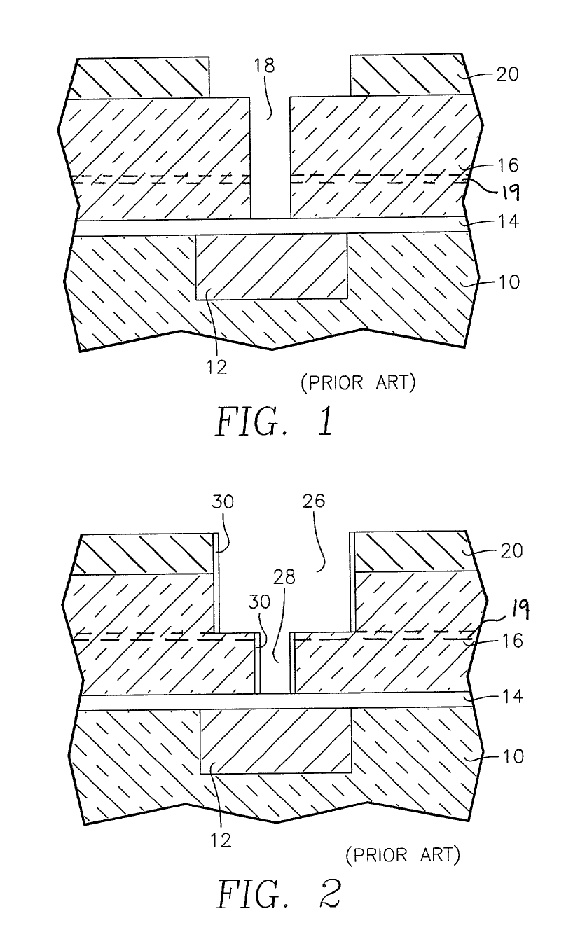

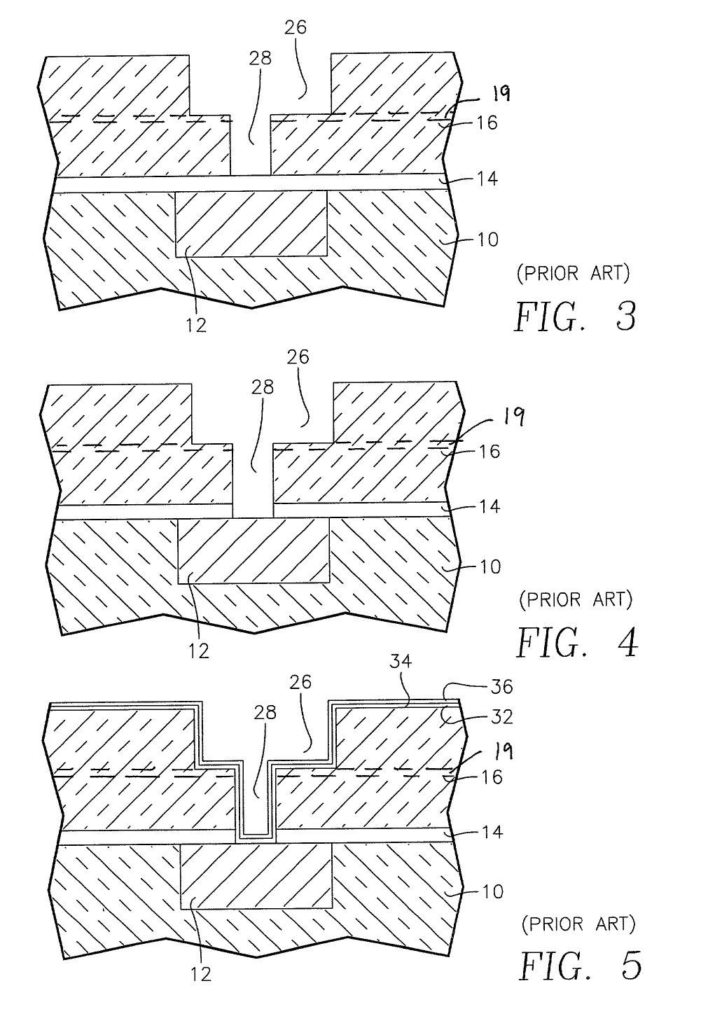

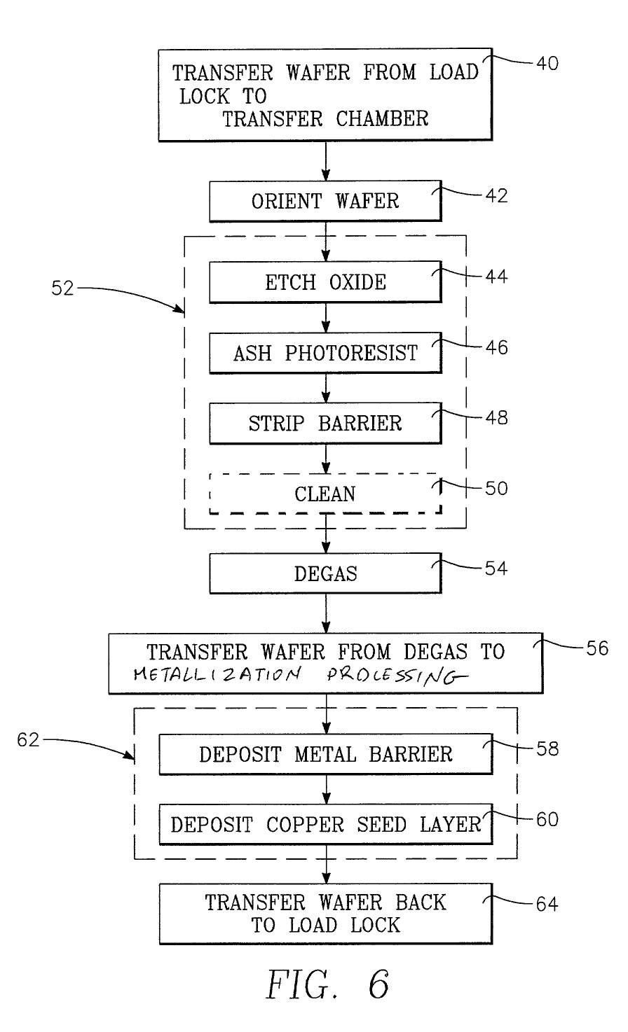

An exemplary integrated process of the invention for etching a via hole and depositing the metal liner layer is presented in the flow diagram of FIG. 6. The process begins with a masked wafer, for example, the structure of FIG. 1 for a dual-damascene trench etch. A number of such wafers are carried in a cassette which is loaded into a load lock of a processing platform. In step 40, one such wafer is transferred from the load lock into an evacuated transfer chamber. The transfer chamber, after system startup, is always held at a pressure of less than 1 Torr, typically below 150 milliTorr. In step 42, the wafer is oriented in an orienter if it has not already been oriented in the factory interface.

In step 44, the inter-level dielectric etch is performed in a reactor attached to the transfer chamber to produce, for example, the structure of FIG. 2, having a trench and associated via etched in the dielectric layer. In step 46, the resist is removed in a plasma ashing process. Etch by products are simultaneously removed. In step 48, the barrier layer at the bottom of the via, e.g., silicon nitride, is stripped in a plasma etching process. Optionally, in step 50, the wafer is cleaned, although an advantage of an embodiment of the invention is that the clean step may be skipped, since the wafer will not be exposed to the atmosphere.

In step 54, the wafer is degassed. The degassing may be performed in the transfer chamber, in a degas chamber, or in a separately pumped passageway between two pressure stages, as will be described below in more details. At this point, the wafer has a fully etch via hole with no barrier layers. Therefore, both the oxide and the underlying copper feature are exposed. In step 56, the wafer is transferred to the metallization processing without exposure to the atmosphere

In step 58, the metal barrier is deposited. This is typically performed by sputtering or physical vapor deposition (PVD), and the metal barrier for copper metallization is typically TaN or Ta/TaN. However, other deposition methods and other barrier compositions are possible. In step 60, a copper seed layer is deposited. When electroplating of copper is subsequently used, the copper seed layer serves as both a nucleation layer and an electroplating electrode. The metal barrier and seed layers constitute a metal liner which is included in the structure of FIG. 5. Finally, in step 64, the wafer is transferred from transfer chamber back to the load lock.

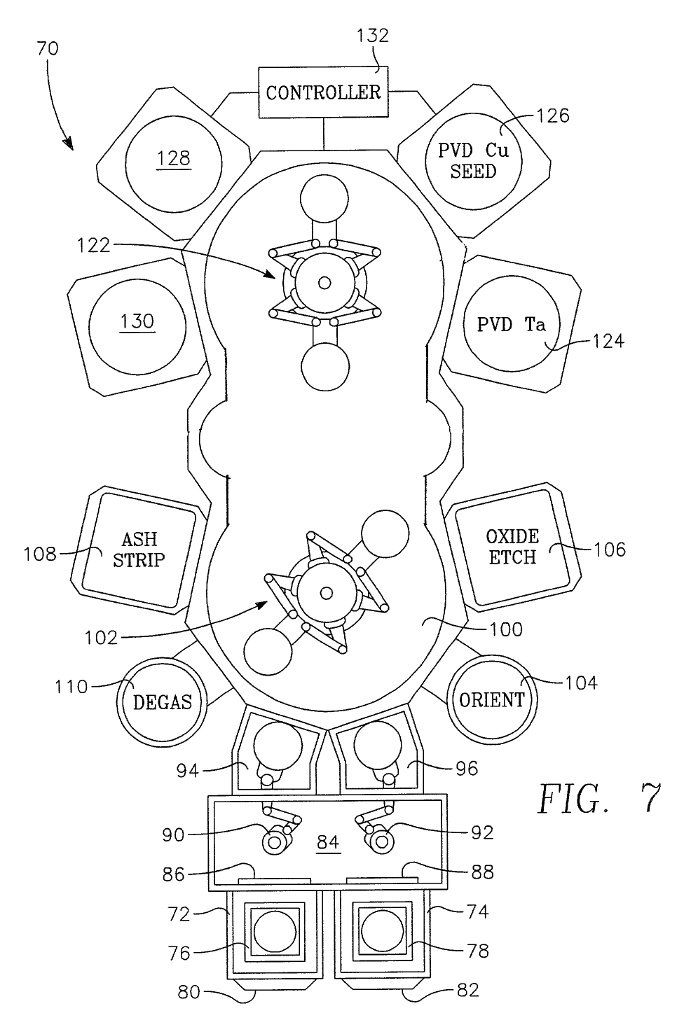

The integrated etch and metal liner process of FIG. 6 may be performed, for example, in a platform (mainframe) 70 illustrated in FIG. 7. Such a platform may be, for example, the Endura SL processing platform available from Applied Materials. This high-capacity system includes at least two loading tables 72, 74 onto which wafer cassettes 76, 78 may be loaded and unloaded. The loading tables 72, 74 are coupled to a factory interface 84 through respective selectively openable doors 86, 88. Once the respective cassette has been loaded its door 86, 88 is opened to allow the load robot 90, 92 located in the factory interface 84 to transfer a wafer between the cassette 76, 78 and a transfer pedestal in a respective one of two load locks 94, 96. Once all the wafers have been transferred to the respective load lock, the loadl lock is pumped down.

The mainframe 70 includes a transfer chamber 100 that is coupled to the other side of the load locks 94, 96. An unillustrated separate vacuum pumping system is connected to the transfer chamber 100 to maintain it at a pressure of no more than 1 Torr and preferably less than 150 milliTorr. A robot 102 is controlled by a computer to remove a wafer from the transfer pedestal of either of the load locks 94, 96. The robot 102 is capable of transferring wafers into and out of all the stations and processing chambers associated with the transfer chamber 100 and can also directly transfer a wafer between the attached stations. In this particular example, a two-blade robot is depicted, each capable of carrying a wafer. Although the blades are rotated together, they are independently projectable and retractable, thus increasing system throughput. Of course, a single blade robot may alternatively be used.

Several processing stations are coupled to the transfer chamber 100 to perform the steps according to the embodiments of the invention, such as those described above with reference to FIG. 6. A wafer orienter 104 may be used to orient the wafer so that alignment indicia on the wafer edge are aligned with corresponding structure in delicate electrostatic chucks and the like. However, the orienter is often instead located in the factory interface 84.

Importantly for one aspect of the invention, an oxide plasma etch reactor 106 is coupled to the transfer chamber 100 to at least etch the oxide to produce the structure of FIG. 2. The nitride and sidewall selectivity required for etching a via hole with a high aspect ratio is accomplished by operating the reactor to cause anisotropic etching of the oxide layer. Selective anisotropic etching often forms a carbonaceous polymer coating. During etching, the polymer forms on non-oxide surfaces and also on the protected oxide sidewalls of the via hole, thereby providing a protective coating. However, care must be taken to prevent excessive polymer formation in a deep narrow hole which may bridge the hole and prevent further oxide etching, in a condition called etch stop. Hung et al. in U.S. Pat. No. 6,174,451 describe that a particularly beneficial etching gas is the fluorocarbon hexafluorobutadiene (C₄F₆) although other fluorocarbon and hydrofluorocarbon etching gases are widely used. It may be desired to add a more polymerizing gas to the C₄F₆, such as difluoromethane (CH₂F₂).

Various types of plasma etch reactors are commonly used for oxide etching and can be used as the plasma etch reactor 106. Two exemplary reactors are magnetically enhanced reactive ion etcher (MERIE) and an inductive decouples plasma reactor. An example of the MERIE type is the eMAX™ oxide etch reactor available from Applied Materials, while an example of the inductive type is the IPS™ oxide etch reactor also available from Applied Materials.

It is possible that the oxide plasma etch reactor 106 performs more steps than just the oxide etching. The inductively coupled IPS™ reactor has been demonstrated to perform the oxide etching, photoresist ashing, and nitride barrier removal by varying its etching gas mixture and adjusting its various power levels. However, it is more conventional to perform the latter two steps in two other chambers or possibly in a single ash/strip plasma reactor, such as the ASP chamber available from Applied Materials. The ash/strip chamber 108 may be a reconfigured and somewhat simplified oxide etch reactor that uses an oxygen plasma with a substantially unbiased pedestal electrode for the photoresist and polymer ashing and a lean, non-polymerizing fluorocarbon-based etch of the barrier layer with a biased pedestal electrode and with the possible addition of selectivity-reducing gases such as oxygen. If a separate plasma ashing reactor is used, it may be a reactor with a remote plasma source, e.g., remote microwave plasma source. The ash/strip chamber 108 (or two chambers performing the steps separately) ash the photoresist and polymer and strip the silicon nitride at the bottom of via hole to produce the structure of FIG. 4.

A separate cleaning reactor may be used to remove any oxide or residue from the exposed contact metal prior to sputtering, as is conventionally done. However, in view of the lack of substantial exposure to air or oxygen after the silicon nitride barrier has been removed, cleaning is not a critical requirement. Indeed, one advantage of the invention is the ability to skip the cleaning method, thereby preventing exposure of the wafer to any further sputtering. Rather, according to embodiments of the invention, after the barrier layer removal, the wafer is transferred to the metallization chamber via the transfer chamber and without exposure to the atmosphere. Separate vacuum pumping systems are provided for at least the oxide etch reactor 106 and the ash/strip reactor 108 so as to allow the first central transfer chamber 100 to always be maintained at a pressure below 1 Torr. As a result, as the wafer is being passed between reactors and to the next stage, it is never exposed to substantial air or humidity.

A separate degas station 110 may also be coupled to the transfer chamber to heat the stripped wafer to remove as much adsorbed oxygen or other gases before the robot 100 transfers the degassed wafer to the metallization processing.

In this exemplary embodiment, a second dual-blade robot 122 located is also located in the transfer chamber 100 and can transfer a wafer between the first robot 102 and any of the metallization stations attached to the transfer chamber 100. The number and type of reactors associated with the metallization process depends upon the desired integrated circuit structure and the form of the via and its liner. However, an exemplary configuration for a copper via includes a first sputtering (PVD) reactor 124 with a tantalum target for sputtering a Ta/TaN barrier layer and a second PVD reactor 126 for with a copper target for sputtering a copper seed layer to produce the structure of FIG. 5. Particularly the copper PVD reactor 124 is advantageously implemented with the previously mentioned SIP⁺™ sputter reactor. However, other types of sputter reactors may be used. Sometimes, a sub-barrier of TiN is used. Also, in some applications, particularly with very high aspect-ratio vias, a chemical vapor deposition (CVD) is used to deposit one or more of the barrier metals or barrier nitrides.

Each of the metallization reactors is selectively isolated from the transfer chamber 100 by a respective slit valve to isolate the transfer chamber 100 from the processing environment and is also pumped by a separate respective vacuum pumping system. Thereby, the transfer chamber 100 is maintained during wafer processing at vacuum. As a result, between the sputter operations performed in the metallization chambers, the exposed metal surfaces are not exposed to significant oxygen or humidity. After completion of the liner layer deposition, the two robots 122, 102 pass the wafer to the load lock, and the wafer is returned to one of the cassettes in the.

The other two reactors 128, 130 may include one or more of these additional reactors or may be a second pair of tantalum and copper PVD reactors so as to increase system throughput. A controller 132 controls the operation of the system including the load locks, the transfer chamber robots, the processing reactors and other parts of the integrated platform.

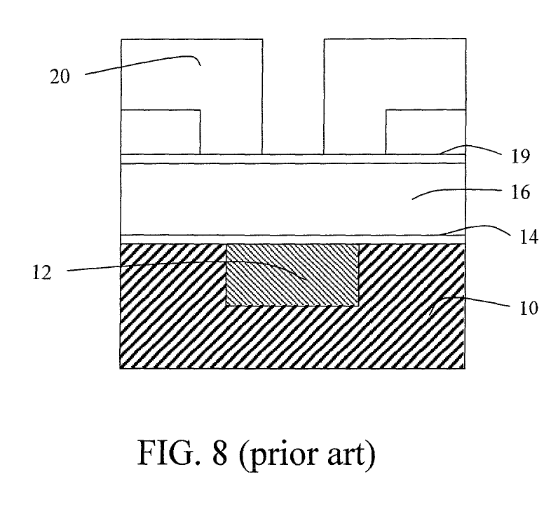

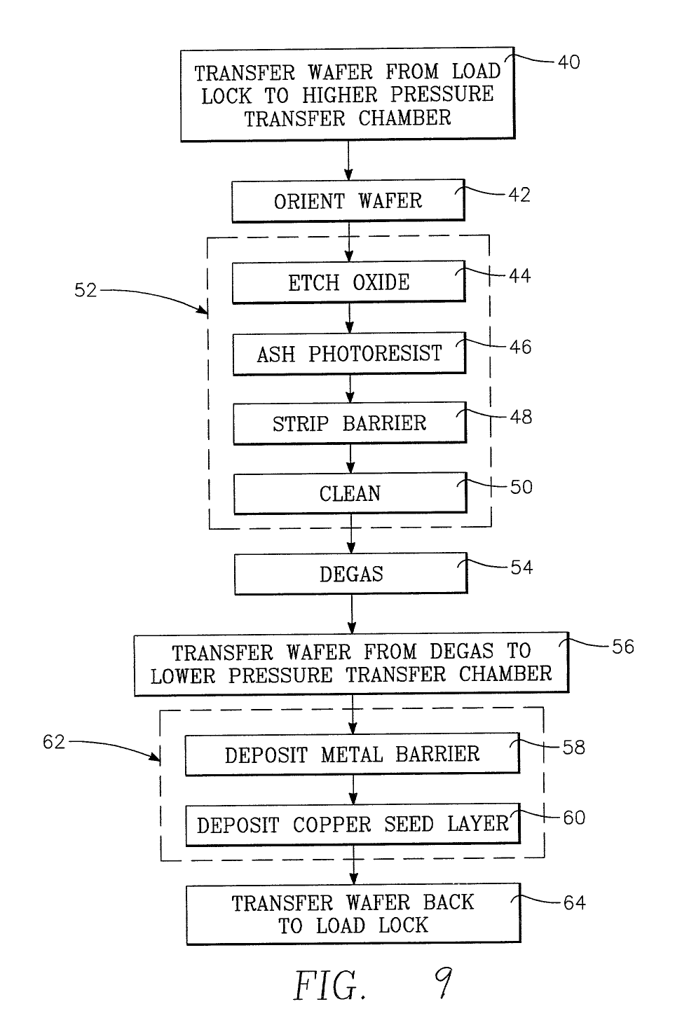

While the exemplary process described above relates to a via first dual damascene process, the same can be done with a trench first process. An exemplary structure for a trench first is depicted in FIG. 8. In this case, the trench has already been etch prior to the processing according to the present invention. Additionally, a mask is provided to delineate the via etch done in the processing according to the invention. Again, the processing for the dual damascene etch and metallization according the embodiments of the invention is done without exposing the wafer to the atmosphere.

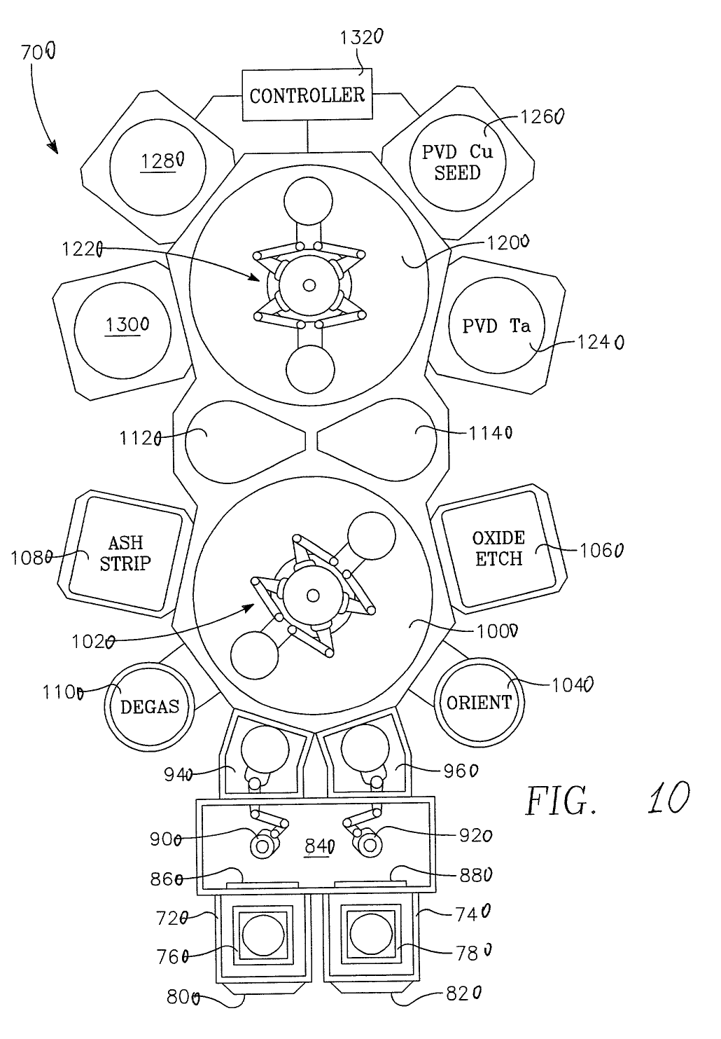

A modified version of the dual damascene process of the invention will now be described with respect to FIG. 9. This embodiment is advantageous when a fluorine-based chemistry is used for the etch processes and there's a need to ensure that no fluorine will reach the metallization chambers. For that purpose, it is advantageous to isolate the etch chambers from the metallization chambers, but still avoid exposing the wafer to the atmosphere. Therefore, in this embodiment a dual-transfer chamber mainframe is used, such as, for example, the Endura™ mainframe available from Applied Materials. The two transfer chambers can be pumped separately and be held at a different vacuum levels is needed. This isolation enables degassing of the wafer prior to introduction of the wafer to the metallization process.

In the following exemplary embodiment, the first transfer chamber is held at a higher vacuum pressure relative to a second low-pressure transfer chamber. In this example, the first transfer chamber is held at a pressure of less than 1 Torr, typically 150 milliTorr, while the second transfer chamber is held at a pressure of no more than 10⁻⁶ Torr, and preferably at a pressure of no more than approximately 10⁻⁸ Torr. An intermediate load lock is provided between the two transfer chambers to provide the isolation between the transfer chambers.

The process may begin with a masked wafer, for example, either the structure of FIG. 1 or FIG. 9. In step 400 the wafer is moved from the load lock into the first transfer chamber and, if necessary is oriented in step 420. Thereafter, steps 440-480 are performed in chambers that are connected to the first transfer chamber. Theses steps are referred to as etching steps 520 which do not require the high vacuum levels of the metallization chambers. Again, clean step 500 is shown as optional.

In step 540, the wafer is degassed. The degassing may be performed in the higher-pressure stage 520 or in a separately pumped intermediate load locks between the two pressure stages. At this point, the wafer has a fully etch via hole with no barrier layers. Therefore, both the oxide and the underlying copper feature are exposed. In step 560, the wafer is transferred from the degassing station to the second, lower-pressure, transfer chamber. In step 580 the metal barrier is deposited and in step 60 a copper seed layer is deposited. Steps 580 and 600 for depositing the metal liner constitute a lower-pressure sequence 620 performed in reactors associated with the lower-pressure transfer chamber.

Finally, in step 640, the wafer is transferred from the lower-pressure transfer chamber back to the load lock, typically through the higher-pressure transfer chamber.

The staged-vacuum process described above is advantageous in that the dirtier etching and cleaning processes as well as the dirty incoming wafer and its photoresist mask are confined to the higher-pressure transfer system while the sputtering processes, which requires a high vacuum, and the processes in which metal is exposed are isolated in the low-pressure stage. Tepman et al. have described a staged-vacuum sputtering platform in U.S. Pat. No. 5,186,718. The exposure of metal to oxygen can be further reduced by performing the barrier strip 480 in the low-pressure stage 620 rather than the high-pressure stage 520.

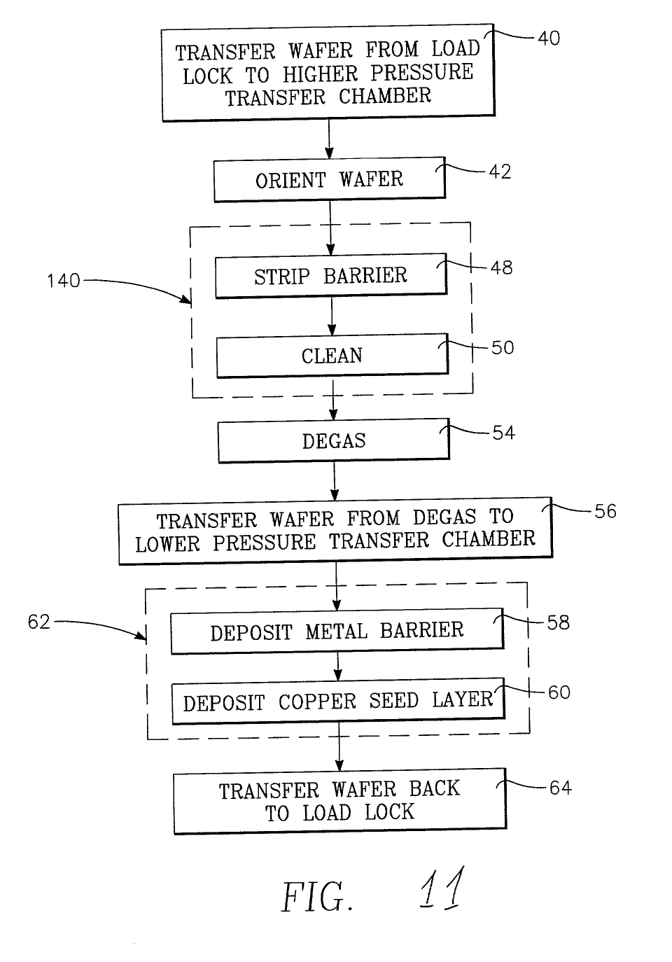

The integrated etch and metal liner process of FIG. 9 may be performed, for example, in a platform 700 illustrated in FIG. 10 based on the Endura™ processing platform. This high-capacity system includes two transfer chambers. A first, higher-pressure central transfer chamber 1000 is coupled to the other side of the load locks 940, 960 to allow a dual-blade robot 1020 to remove a wafer from the transfer pedestal of either of the load locks 940, 960. The robot 1020 is capable of transferring wafers into and out of all the stations associated with the first transfer chamber 1000 and can also directly transfer a wafer between the attached stations. An unillustrated separate vacuum pumping system is connected to the low vacuum central transfer chamber 1000 to maintain it at a pressure of no more than 1 Torr and preferably at approximately 150 milliTorr or below.

Several processing stations are coupled to the first, low vacuum central transfer chamber 1000 to perform the steps that are generally considered dirty and may utilize fluorine chemistry. Notably, for one aspect of the invention, an oxide plasma etch reactor 1060 is coupled to the first transfer chamber 1000 to at least etch the oxide to produce the structure of FIG. 2. It is possible that the oxide plasma etch reactor 1060 performs more steps than just the oxide etching. The inductively coupled IPS reactor has been demonstrated to perform the oxide etching, photoresist ashing, and barrier layer removal by varying its etching gas mixture and adjusting its various power levels. However, it is more conventional to perform the latter two steps in two other chambers or possibly in a single ash/strip plasma reactor. The ash/strip chamber 1080 may be also attached to the first transfer chamber.

A separate cleaning reactor may be used to remove any oxide or residue from the exposed contact metal prior to sputtering, as is conventionally done. However, in view of the lack of substantial exposure to air or oxygen after the silicon nitride barrier has been removed, cleaning is not a critical requirement and is advantageously not performed according to this embodiment.

Separate vacuum pumping systems are provided for at least the oxide etch reactor 1060 and the ash/strip reactor 108 so as to allow the first transfer chamber 1000 to always be maintained at a pressure below 1 Torr. As a result, as the wafer is being passed between reactors and to the next stage, it is never exposed to substantial air or humidity.

A separate degas station 1100 may also be coupled to the first transfer chamber to heat the stripped wafer to remove as much adsorbed oxygen or other gases before the robot 1000 transfers the degassed wafer to one of two platform pass through chambers 1120, 1140 arranged in parallel between the first, higher-pressure central transfer chamber 1000 and a second, lower-pressure (high vacuum) central transfer chamber 1200. A vacuum pumping system attached to the second central transfer chamber 1200 is capable of maintaining it at a pressure of no more than 10⁻⁶ Torr, and preferably no more than 10⁻⁸ Torr. The latter pressure is that associated with sputtering reactors. Each of the platform pass through chambers 1120, 1140 has its own vacuum pumping system and pair of selectively openable slit valves between it and the two transfer chambers 1000, 1200. Thereby, the wafer may be passed from the first, low vacuum transfer chamber 1000 to the second, high vacuum transfer chamber 1200 without degrading the stronger vacuum of the latter. It is also possible to attach a processing station, such as a preclean or a degasser, to one of the platform pass through chambers 1120, 1140.

A second dual-blade robot 1220 located in the second transfer chamber 1200 can transfer a wafer between either of the platform pass through chambers 1120, 1140 and any of the other stations attached to the second transfer chamber 1200. The number and type of reactors associated with the second transfer chamber 120 depends upon the desired integrated circuit structure and the form of the via and its liner. However, an exemplary configuration for a copper via includes a first sputtering (PVD) reactor 1240 with a tantalum target for sputtering a Ta/TaN barrier layer and a second PVD reactor 1260 for with a copper target for sputtering a copper seed layer to produce the structure of FIG. 5. Particularly the copper PVD reactor 1240 is advantageously implemented with the previously mentioned SIP⁺ sputter reactor. However, other types of sputter reactors may be used. Sometimes, a sub-barrier of TiN is used. Also, in some applications, particularly with very high aspect-ratio vias, a chemical vapor deposition (CVD) is used to deposit one or more of the barrier metals or barrier nitrides.

Each of the reactors associated with the second transfer chamber 1200 is selectively isolated from it by a respective slit valve to isolate the second transfer chamber 1200 from the processing environment and is also pumped by a separate respective vacuum pumping system. Thereby, the second transfer chamber 1200 is maintained during wafer processing at a pressure of no more than 10⁻⁶ Torr and preferably no more than 10⁻⁸ Torr. As a result, between the sputter operations performed in the chambers of the second transfer chamber, the exposed metal surfaces are not exposed to significant oxygen or humidity. After completion of the liner layer deposition, the two robots 1220, 1020 pass the wafer through one of the platform pass through chambers 1120, 1140 to the load lock, and the wafer is returned to one of the cassettes 760, 780.

The other two reactors 1280, 1300 available on high-vacuum stage of the Endura platform may include one or more of these additional reactors or may be a second pair of tantalum and copper PVD reactors so as to increase system throughput. Also, because the stop layer strip reactor involves a clean etching chemistry, it is possible to move it to the second, lower-pressure transfer chamber 1200, thereby assuring that the underlying copper feature is not exposed to more than 10⁻⁶ Torr of pressure once the silicon nitride has been removed.

A controller 1320 controls the operation of the system including the load locks, the transfer chambers, the processing reactors and other parts of the integrated platform.

The use of the platform of FIG. 10 in the performance of the process of FIG. 9 offers several advantages. The traditional preclean step, particularly involving a wet clean between the etching sequence and the sputtering sequence, is no longer critical and may be eliminated. Not only are the process and associated apparatus simplified, but the lack of cleaning improves the control of critical dimension (CD) because the preclean step usually causes faceting of the top of the via hole. Many of the ultra low-k dielectrics are particularly susceptible to erosion and sputtering during the argon sputtering used for precleaning.

Secondly, since the dielectric etch is followed by sputtering without exposing the wafer to atmosphere, the low-k dielectric surface existing upon completion of the etch is not exposed to air and humidity, thereby avoiding an increase in the k value.

Thirdly, because the entire integrated process is performed on one platform, the work in progress (WIP) queue of conventional non-integrated processing is eliminated, thus reducing the cycle time from etch to CMP.

Fourthly, vacuum integration avoids the prolonged exposure of the copper contacts to atmosphere and thus improves device yield and decreases via resistance because of the elimination of the variability introduced by the distribution of WIP queuing times. Because of the reduction in the number of atmospheric wafer transfers between platforms, particles are less likely to deposit on wafers, thus increasing device yield and reliability.

The invention can be applied to a subset of the above described process in a process stretching from barrier removal to liner deposition, as illustrated in the flow diagram of FIG. 11. The process assumes that, as the wafer is being loaded into the integrated platform, the oxide has already been etched and the photoresist and polymer have been ashed but that the protective silicon nitride barrier layer remains at the bottom of the via hole. Hence, a higher-pressure sequence 1400 does not include the oxide etching or ashing but includes the previously described barrier stripping step 480 and cleaning step 500, if the latter is needed. Thereafter, the process remains quite similar to that of FIGS. 6 or 9 with the lower-pressure sequence 620 including the two sputtering steps 580, 600.

This process may be practiced on an integrated platform similar to that of FIG. 7 or in a platform similar to that of FIG. 10, in which the barrier removal and cleaning steps are performed in the higher-pressure stage and the sputtering steps in the lower-pressure stage.

In this process also, the oxide layer and the copper contact surface are protected from air between the silicon nitride barrier removal and the metal liner deposition. Furthermore, the variable queuing problems described above are avoided.

The invention is particularly useful with copper metallization in a dual-damascene structure using low-k dielectrics. However, the invention is not limited to any one of these restrictions. It may be applied to conventional silica dielectrics, to uniform contact and via holes, and to other metallizations such as aluminum.

Although the invention relies on a complexly configured platform, in fact, the overall system and its operation are simplified since only one platform is used for all the steps and the manual loading and unloading of cassettes is simplified. Queuing is simplified and is computer controlled. Device performance is improved and made more uniform.

1. An integrated etch and metal liner process of a substrate including a stop layer covered with a dielectric layer having a dielectric constant k<4 and covered with a patterned mask material, comprising the steps of:
transferring the substrate into a transfer chamber held at below atmospheric pressure;
transferring the substrate from the transfer chamber to an etching chamber and etching the substrate according to said patterned mask material through said oxide layer to said etch stop layer to form a hole in said oxide layer;
ashing said mask material;
removing said etch stop layer exposed at a bottom of said hole;
transferring said substrate to a metallization chamber through said transfer chamber and without exposing the substrate to an atmospheric pressure;
depositing a barrier layer in said metallization chamber; and
depositing a metal seed layer.

2. The process of claim 1, wherein said metal seed layer is a copper seed layer.

3. The process of claim 1, wherein said barrier layer comprises tantalum.

4. The process of claim 1, wherein at least one of said depositing steps is a sputtering step.

5. An integrated etch and metal liner process of a substrate including a stop layer covered with a dielectric layer having a dielectric constant k<4 and covered with a patterned mask material, comprising the steps of:
etching according to said patterned mask material through said oxide layer to said etch stop layer to form a hole in said oxide layer;
ashing said mask material;
removing said etch stop layer exposed at a bottom of said hole;
transferring said wafer to a transfer chamber maintained at a sub-atmospheric pressure;
in a reactor coupled to said transfer chamber, depositing a barrier layer;
in a reactor coupled to said transfer chamber, depositing a metal seed layer; and,
wherein said wafer is maintained between said etching, ashing and removing steps and during said transferring step at a sub-atmospheric pressure.

6. The process of claim 5, wherein said barrier layer comprises tantalum.

7. The process of claim 5, wherein at least one of said depositing steps is a sputtering step.

8. The process of claim 5, wherein said transfer chamber is maintained at a pressure of less than 10⁻⁶ Torr.

9. An integrated etch and metal liner process of a substrate including a stop layer covered with an oxide layer covered with a patterned photoresist mask, comprising the steps of:
a first step of transferring said substrate into a first transfer chamber maintained at a pressure of no more than 1 Torr;
a second step of transferring said substrate from said first transfer chamber to an oxide etch reactor;
in said oxide etch reactor, etching said oxide layer according to said mask to form a hole in said oxide layer;
a third step of transferring said substrate from said oxide etch reactor through said first transfer chamber to a second transfer chamber maintained at a pressure of no more than 10⁻⁶ Torr;
a fourth step of transferring said substrate from said second transfer chamber to at least one reactor to deposit a layer in said hole.

10. The process of claim 9, further comprising ashing said photoresist layer in said oxide etch reactor.

11. The process of claim 9, further comprising:
a fifth step of transferring said wafer from said oxide etch reactor through said first transfer chamber to a plasma ashing reactor; and
in said plasma ashing reactor, ashing said photoresist layer;
wherein said third step of transferring comprises transferring said substrate from said plasma ashing reactor through said first transfer chamber to said second transfer chamber.

12. An integrated processing platform, comprising:
a first vacuum transfer chamber;
a second vacuum transfer chamber;
a doubly gated vacuum passageway linking said first and second vacuum transfer chambers;
an oxide etch reactor connected through a openable slit valve to said first vacuum transfer chamber;
a deposition chamber connected through an openable slit valve to said second transfer chamber; and
a robot for transferring substrates between said first and second vacuum transfer chambers, said etch chamber, and said deposition chamber.

13. The platform of claim 12, wherein said first vacuum transfer chamber is maintained at a pressure of no more than 150 Torr and said second vacuum transfer chamber is maintained at a pressure of no more than 10⁻⁶ Torr.
